(19) United States
(12) Patent Application Publication
(10) Pub. No.: US 2018/0143240 A1
(43) Pub. Date: May 24, 2018

(54) SYSTEMS AND METHODS FOR ASSESSING CONDITION OF A SENSOR

(71) Applicant: Sikorsky Aircraft Corporation, Stratford, CT (US)

(72) Inventors: Jeremy Sheldon, Henrietta, NY (US); Christopher M. Minnella, Pittsford, NY (US)

(21) Appl. No.: 15/576,221

(22) PCT Filed: May 20, 2016
(86) PCT No.: PCT/US16/33425

§ 371 Date: Nov. 21, 2017

Related U.S. Application Data
(60) Provisional application No. 62/167,465, filed on May 28, 2015.

(51) Int. Cl. G01R 31/28; G01R 31/27; G01R 31/3187; G01D 3/08

(52) U.S. Cl. CPC G01R 31/2829; G01R 31/27; G01R 31/36; G01D 3/08; G01R 31/3187

(57) ABSTRACT

A method for assessing the condition of a sensor includes applying a diagnostic signal to the sensor using a controller and receiving a dynamic output response. The dynamic output response includes a voltage transient and return to a baseline sensor output voltage. The dynamic output response is thereafter compared to a reference output response, and condition of the sensor is indicated as unreliable if the dynamic output response differs from the reference output response by a predetermined amount for a dynamic output response output parameter.

### CROSS REFERENCE TO RELATED APPLICATION

This application claims priority to and benefit of U.S. Provisional Application No. 62/167,465, filed May 28, 2015, which is incorporated by reference herein in its entirety.

### BACKGROUND OF THE INVENTION

### 1. Field of the Invention

The present disclosure relates to health monitoring systems, and more particularly to assessing the health of sensors employed by health monitoring systems.

### 2. Description of Related Art

Vehicles like rotorcraft commonly include health and usage monitoring systems (HUMS) that provide data indicative of the health of the aircraft and aircraft systems. Such systems generally include sensors coupled to vehicle systems and components and which are communicative with electronics to report vibration, temperature, and other conditions experienced by mechanical or electrical components during operation. One challenge to such systems is that the sensors incorporated into HUMS can degrade and/or fail during operation, and that the degradation or failure may not be readily cognizable to HUMS. Absent recognition that the sensor itself has failed, data provided by the sensor can cause HUMS to provide inaccurate assessment of the mechanical health of vehicle mechanical components, potentially inducing unnecessary downtime upon an otherwise health vehicular system. Accordingly, some HUMS systems employ strategies such as built-in-test events, direct current bias voltage checks, and sensor output signal screening for purposes of identifying sensors likely to generate data which is suspect or may be misrepresentative of the actual state of a monitored mechanical component.

Such conventional methods and systems have generally been considered satisfactory for their intended purpose. However, there is still a need in the art for improved systems and methods for monitoring sensor health. The present disclosure provides a solution for this need.

### SUMMARY OF THE INVENTION

A method for assessing the condition of a powered sensor includes applying a diagnostic signal to the sensor, such as a voltage or current, and receiving an output dynamic output response. The dynamic output response includes a voltage transient and return to a baseline sensor output voltage. The dynamic output response is compared to a reference output response and condition of the sensor is indicated as unreliable if the dynamic output response differs from the reference output response by a predetermined amount for a dynamic output response parameter.

In certain embodiments the sensor can be a powered sensor. Applying the diagnostic signal to the sensor can include disconnecting the sensor from a power supply, such as by issuing a disconnect command from the controller. Changing the voltage applied to the sensor can include connecting the sensor to a power supply. A first dynamic output responses can be received after disconnecting the sensor from the power supply, a second dynamic output response can be received after re-connecting the sensor to the power supply, and either or both can be compared to disconnect and re-connect reference output responses. The method can form a module of a built-in-test (BIT) event, a standalone built-in test event, or as module of a diagnostic utility for assessing sensor health.

In accordance with certain embodiments, comparing the dynamic output response with the reference output response can include comparing voltage traces of the dynamic output response and reference output response. For example, a time interval indicated decay of the transient from a peak magnitude to baseline can be compared to a time interval indicated in the reference output response. Comparison can also include a comparison of the rate of decay of the transient relative to rate of decay indicated in the reference output response, or any other parameter difference indicative of a problem such as an intermittent open, short, or other electrical problem in the sensor or sensor circuit. The reference output response can be a reference output response recorded on a memory and acquired while the sensor was in a known good condition. The reference output response can, alternatively or additionally, be a dynamic output response of a second accelerometer that the controller disconnected and/or reconnected to the power supply in concert with the first accelerometer. Comparison can be by way of cross-correlating transient responses associated with voltage changes applied contemporaneously to both the first and second sensors.

It is also contemplated that, in certain embodiments, the sensor includes an accelerometer. The accelerometer can be coupled to a mechanical component of a rotary-wing aircraft. The mechanical component can be a blade, a gearbox, airframe structural element, or any other element of diagnostic interest. The accelerometer can be an integrated electronic piezoelectric accelerometer. Health of one or more accelerometers of a common type can be determined by disconnecting and re-connecting the accelerometers on an ad hoc basis while the accelerometers (or other types of sensor) are integrated into an aircraft health and usage monitoring system.

A sensor condition monitoring system includes a sensor configured to monitor the health of a mechanical component of an aircraft, a power supply connectable to the sensor, a controller operatively associated with the power supply, and a memory communicative with the processor. The memory has instruction recorded thereon that, when read by the processor, cause the processor to execute steps of the methods relative above.

These and other features of the systems and methods of the subject disclosure will become more readily apparent to those skilled in the art from the following detailed description of the preferred embodiments taken in conjunction with the drawings.

### BRIEF DESCRIPTION OF THE DRAWINGS

So that those skilled in the art to which the subject disclosure appertains will readily understand how to make and use the devices and methods of the subject disclosure without undue experimentation, embodiments thereof will be described in detail herein below with reference to certain figures, wherein:

FIG. 1 is a schematic view of an exemplary embodiment of a rotorcraft constructed in accordance with the present disclosure, showing a sensor condition monitoring system and sensors coupled to the rotorcraft;

FIG. 2 is a schematic view of the sensor condition monitoring system of FIG. 1, showing a controller operatively associated with a sensor power supply and the sensors;

FIG. 3 is a diagram of a method of assessing the condition of a sensor by comparing a dynamic output voltage response with a previously acquired reference output response;

FIG. 4 shows a method of assessing the condition of a sensor including comparing sensor dynamic output response following a power disconnect and a power re-connect event, according to an embodiment; and

FIG. 5 is a graph of dynamic and reference output responses for an exemplary accelerometer following power connect and disconnect events, examples of performance output parameters being indicated.

### DETAILED DESCRIPTION OF THE PREFERRED EMBODIMENTS

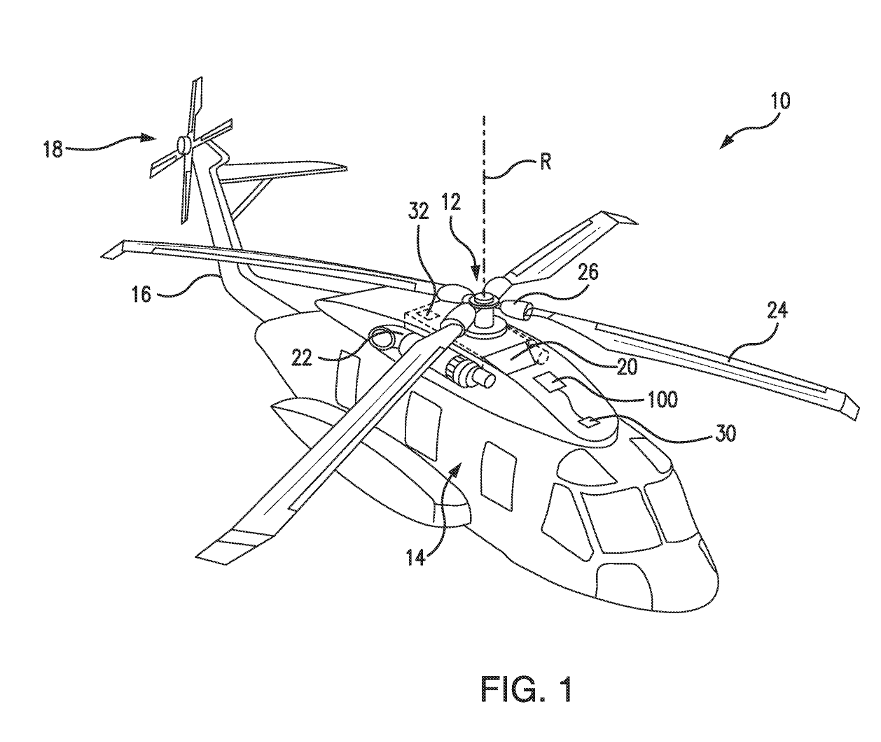

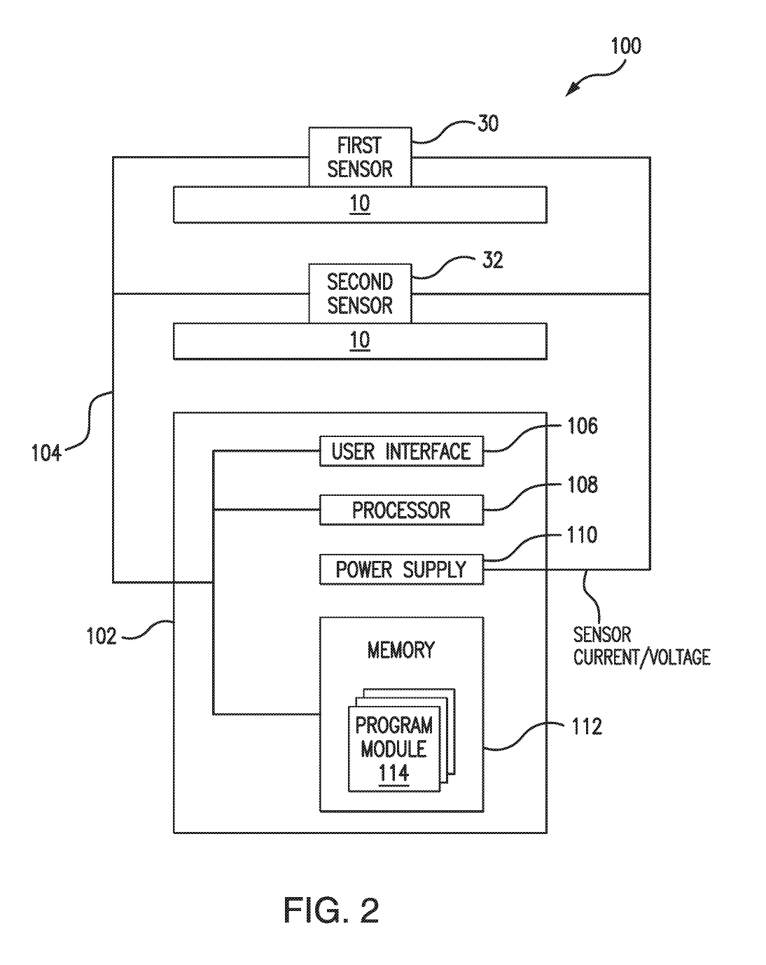

Reference will now be made to the drawings wherein like reference numerals identify similar structural features or aspects of the subject disclosure. For purposes of explanation and illustration, and not limitation, a partial view of an exemplary embodiment of a system for monitoring the condition of sensors coupled to mechanical components of a rotorcraft in accordance with the disclosure is shown in FIG. 1 and is designated generally by reference character 100. Other embodiments of systems and method for sensor condition monitoring in accordance with the disclosure, or aspects thereof, are provided in FIGS. 2-5, as will be described. The systems and methods described herein can be used for health and usage monitoring systems (HUMS), such as in rotary-wing aircraft like helicopters.

With ref to FIG. 1, exemplary vertical takeoff and landing (VTOL) rotary-wing aircraft 10 is shown schematically. Aircraft 10 in the disclosed, non-limiting embodiment includes a main rotor system 12 supported by an airframe 14 having an extending tail 16 which mounts a tail rotor system 18, such as an anti-torque system. One or more engines 22 drive main rotor system 12 through a main gearbox 20. Main rotor system 12 includes a plurality of rotor blades 24 mounted to a rotor hub 26. Although a particular helicopter configuration is illustrated and described in the disclosed embodiment, other terrestrial, marine, and air vehicles, as well as fixed structures will also benefit from this disclosure.

A first sensor 30 for a HUMS system is mechanically connected to a mechanical component of aircraft 10. As illustrated in FIG. 1, first sensor 30 is connected to airframe 14 for purposes of measuring vibration in airframe 14 of diagnostic interest. In embodiments, aircraft 10 includes a second sensor 32 connected to an aircraft mechanical component. In certain embodiments, both first sensor 30 and second sensor 32 include accelerometers coupled to mechanical components of aircraft 10, such as airframe 14, main rotor system 12, or main gearbox 20, for measuring and reporting vibration levels associated with the mechanical component.

Either or both of first sensor 30 and second sensor 32 may include an integrated electronic piezoelectric (IEPE) accelerometer. The IEPE accelerometer may include an electronic amplifier, and connects to a power supply 110 (shown in FIG. 2) by a single, two-pole coaxial cable for both receiving input power and providing a voltage output response that corresponds to sensor vibration. The power supply provides a constant current to an inner conductor of the coaxial cable within a predetermined fixed range. The IEPE accelerometer provides an output signal as a measurable voltage change that is indicative of vibration levels experienced by the sensor. In embodiments, where there is no measurable vibration at first sensor 30, the output voltage reverts to a baseline that may be about zero (0) volts.

With reference to FIG. 2, a system 100 for assessing the condition of a sensor is shown. System 100 includes a controller 102 connected to both first sensor 30 and, optionally, second sensor 32. Controller 102 generally includes a user interface 106, a processor 108, and a memory 112. A communications bus 104 interconnects processor 108 with user interface 106 and memory 112.

Memory 112 has a plurality of program modules 114 recorded thereon that, when read by processor 108, cause processor 108 to undertake certain actions that are detailed below. Among the actions is connecting and disconnecting power supply 110 to one or more sensors coupled to mechanical components of aircraft 10 (shown in FIG. 1). For purpose of illustration and not for limitation, FIG. 2 shows processor 108 as operatively connected to power supply 110 for disconnecting and reconnecting power supply 110 to both first sensor 30 and second sensor 32. Processor 108 is also communicative with both first sensor 30 and second sensor 32 for receiving output voltage therefrom.

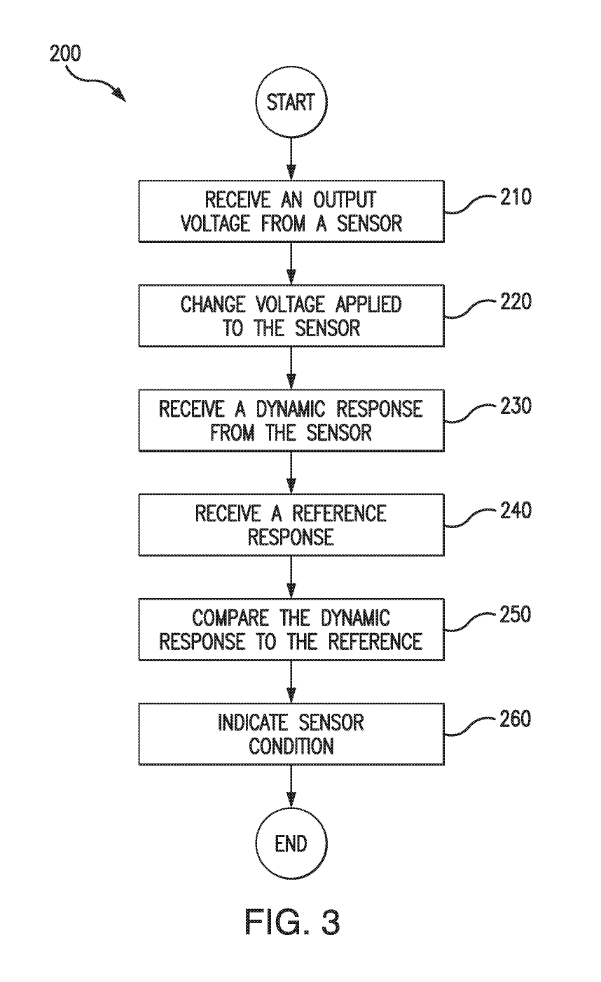

With reference to FIG. 3, a method 200 of assessing the condition of a sensor is shown. Method 200 includes receiving an output voltage from a sensor, e.g. first sensor 30 and/or second sensor 32, as shown with box 210. Method 200 also includes applying a diagnostic signal to the sensor using a controller, e.g. controller 102, as shown with box 220. The diagnostic signal may be a voltage or a current applied to the sensor. Applying the diagnostic signal may include disconnecting the sensor from a voltage supply, e.g. power supply 110. Applying the diagnostic signal may also include re-connecting the sensor to the voltage supply.

Changing the voltage applied to the sensor causes the sensor to issue a dynamic output response that includes a voltage transient and a voltage return to baseline. Method 200 includes receiving the dynamic output response, as shown with box 230, and further receiving a reference output voltage response, as shown with box 240. The dynamic output response can be a previously acquired reference output response, such as an output response acquired when a particular sensor was previously in a known-good condition, and may be acquired by applying a diagnostic signal to the sensor with a current or voltage that is different than that ordinarily applied to the sensor to acquire a measurement. Once acquired, the dynamic output response is compared with the reference output response, as shown with box 250, and condition of the sensor is indicated as unreliable if the dynamic output response differs from the reference output response by a predetermined amount for a dynamic output response parameter, as shown with box 260.

In embodiments, changing the voltage applied to the sensor provokes a dynamic output response peculiar to the type of sensor. For example, IEPE accelerometers may respond to power disconnect events by outputting a negative voltage transient. The negative voltage transient can relative to a baseline output voltage of the IEPE accelerometer, and can have characteristic decay interval during which the sensor output voltage returns to the baseline voltage.

IEPE accelerometers may respond to power re-connect events by outputting a positive voltage transient. The positive voltage transient can be relative to the IEPE accelerometer baseline output voltage, and can have a characteristic decay interval during which the sensor output voltage returns to the baseline voltage. As will be appreciated by those of skill in the art in view of the present disclosure, the dynamic output response to a given power change (e.g. connect or disconnect events) should be consistent absent a change to the condition of the sensor. Consequently, signal analysis of sensor output immediately following disconnect and connect events can provide indication of the condition of the sensor, such as whether intermittent short or open circuit conditions may be affecting the sensor.

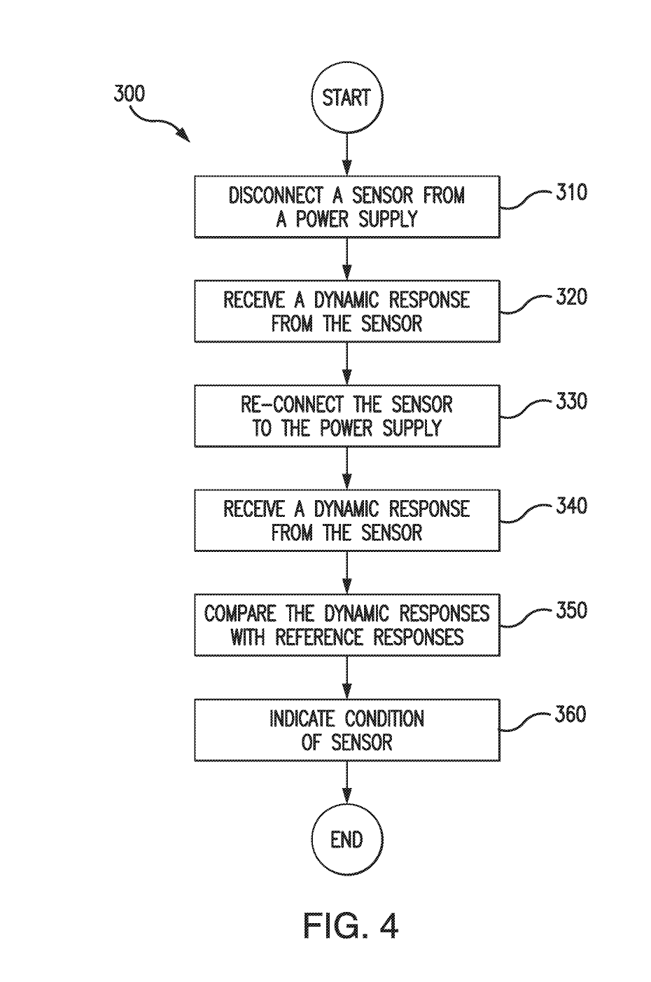

With reference to FIG. 4, a method 300 of assessing condition of a sensor is shown, according to an embodiment. Method 300 includes disconnecting the sensor from a power supply, as shown with box 310, and receiving thereafter a dynamic output response in voltage output from the sensor associated with the disconnect event, as shown with box 320. Method 300 also includes re-connecting the sensor to a power supply, as shown with box 330, and receiving thereafter a dynamic output response in voltage output from the sensor associated with the re-connect event, as shown with box 340.

Method 300 further includes comparing the dynamic output responses with reference output responses, as shown with box 350. The reference output response may include a predetermined transient voltage trace stored in a memory, e.g. memory 112 (shown in FIG. 2). The reference output response may include a voltage transient acquired from another sensor, e.g. second sensor 32 (shown in FIG. 2).

The voltage transient can be acquired contemporaneously with the dynamic output response acquired from the first sensor (e.g. first sensor 30, shown in FIG. 2), such as from common disconnect or re-connect events, or from a second sensor (e.g. second sensor 32, shown in FIG. 2) connected to the same power supply as the first sensor. Based on the comparison, condition of the sensor is indicated, as shown with box 360. Indication may be by setting a flag state in software, illuminating a lamp, messaging a maintainer, or any other suitable mechanism for providing indication that the sensor output may be unreliable.

In embodiments, comparing the dynamic output response with the reference output response includes application of a signal comparison algorithm. For example, in certain embodiments, the comparison includes at least one of (a) comparing maxima or minima of the dynamic and reference output responses, and indicating that the sensor may be unreliable if the differential exceeds a predetermined amount, (b) comparing time intervals between occurrence of the transient maxima or minima and decay of the transient to baseline for the dynamic and reference output responses, and (c) comparing slopes of the dynamic and reference output responses at intervals between transient maxima or minima and subsequent return to baseline. In embodiments, cross-correlation of dynamic output responses of the first and second sensors may be employed in making the comparison.

Optionally, method 300 may be included as a module of a built-in-test (BIT) event, a standalone BIT, or as an ad hoc diagnostic test event. As a BIT module or standalone BIT, method 300 checks the condition of the accelerometer upon when power is initially connected to the system including the first and second accelerometer. Sensor condition can also be assessed on an ad hoc basis that may or may not coincide with the initialization of the accelerometer system.

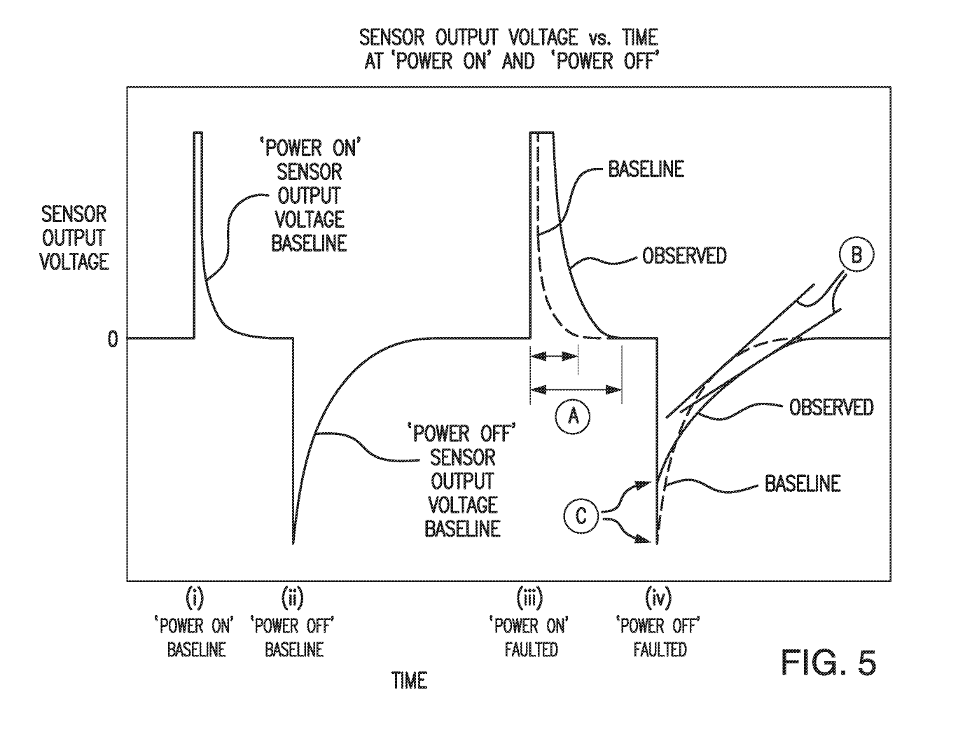

With reference to FIG. 5, a chart of sensor voltage output is shown. From the left-hand side to right-hand side, the chart shows exemplary voltage output traces immediately following ‘power on’ events (connecting power) and ‘power off’ events (disconnecting power) for a sensor, e.g. first sensor 30 and/or second sensor 32 (shown in FIG. 1). In this respect a first ‘power on’ event (i) and a first ‘power off’ event (ii) illustrate exemplary baseline sensor output voltage responses when the sensor is in a known good condition and where the sensor output is reliable. A second ‘power on’ event (iii) and a second ‘power off’ event (iv) illustrate exemplary faulted sensor output voltages, when sensor output may not be reliable.

As will be appreciated, one or more differences can exist between sensor output voltage when the sensor is faulted relative to when the sensor is in a baseline condition following a given ‘power on’ or ‘power off’ event. For example, as indicated at A, the time required for sensor output voltage to decay may differ between exemplary baseline ‘power on’ event (i) and exemplary faulted ‘power on’ event (iii). Alternative (or additionally), the rate of sensor output voltage decay may differ between exemplary baseline ‘power off’ event (ii) and exemplary faulted ‘power off’ event (iv), as indicated at B. The extreme of sensor output voltage following exemplary faulted ‘power off’ event (iv) may differ from exemplary baseline ‘power off’ event (ii), as indicated at C in the chart. One or more of these differences and/or other differences can be utilized to determine the health of the sensor, generally without requiring insertion of diagnostic equipment or disturbing the sensor installation.

Returning to FIG. 2, user interface 106 includes any suitable input, such as a keyboard or touch screen, which enables a user to communicate information and command selections to processor 108. User interface 106 may also include an output device such as a display, e.g., a multi-function display, or a mailer program module. User interface 106 may also further include an input device such as a mouse, touchpad, and/or keyboard, which allows a user to manipulate the display for communicating additional information and command selections to processor 108.

Processor 108 is preferably an electronic device configured of logic circuitry that responds to and executes instructions. Memory 112 is preferably a computer-readable medium encoded with a computer program. In this regard, memory 112 stores data and instructions readable and executable by processor 108 for controlling the operation of processor 108. Memory 112 may be implemented in a random access memory (RAM), a hard drive, a read only memory (ROM), or a combination thereof.

Program module 114 contains instructions for controlling processor 108 to execute the methods described herein. For example, under control of program module 114, processor 108 issues instructions to disconnect and re-connect power supply 110 from first accelerometer 30 and second sensor 32. Program module 114 can also include geometric information relating to structure. It is to be appreciated that the term “module” is used herein to denote a functional operation that may be embodied either as a stand-alone component or as an integrated configuration of a plurality of sub-ordinate components. Thus, program module 114 may be implemented as a single module or as a plurality of modules that operate in cooperation with one another. Moreover, although program module 114 is described herein as being installed in memory 112, and therefore being implemented in software, it could be implemented in any of hardware (e.g., electronic circuitry), firmware, software, or a combination thereof.

Processor 108 outputs, to user interface 106, a result of an execution of the methods described herein. Alternatively, processor 108 could direct the output to a remote device (not shown), via a network connected to communications bus 104. It is also to be appreciated that while program module 114 is indicated as already loaded into memory 112, it may be configured on a storage medium (not shown for clarity purposes) for subsequent loading into memory 112. The storage medium may also be a computer-readable medium encoded with a computer program, and can be any conventional storage medium that stores program module 114 thereon in tangible form. Examples of suitable storage mediums include floppy disks, compact disks, magnetic tape, read only memory, optical storage media, universal serial bus (USB) flash drive, solid-state storage devices (SSD), or compact flash cards. Alternatively, the storage medium can be a random access memory, or other type of electronic storage, located on a remote storage system and coupled to controller 102 via a network.

The methods and systems of the present disclosure, as described above and shown in the drawings, provide for sensor assessment systems and method with superior properties including ad hoc sensor assessment functionality. While the apparatus and methods of the subject disclosure have been shown and described with reference to preferred embodiments, those skilled in the art will readily appreciate that changes and/or modifications may be made thereto without departing from the scope of the subject disclosure.

1. A method of assessing condition of a sensor, comprising:
applying a diagnostic signal to a sensor using a controller;
receiving a dynamic output response from the sensor, wherein the dynamic output response includes a transient and a return from a baseline sensor output voltage;
comparing the dynamic output response to a reference output response; and
indicating that the sensor is unreliable if the dynamic output response differs from the reference output response by a predetermined value for a dynamic output response parameter.

2. A method as recited in claim 1, wherein applying a diagnostic signal to the sensor includes disconnecting the sensor from a sensor power supply.

3. A method as recited in claim 1, wherein receiving a dynamic output response includes receiving a negative transient voltage.

4. A method as recited in claim 1, wherein comparing the dynamic and reference output responses includes comparing decay duration of the transient to duration of decay in the reference output response.

5. A method as recited in claim 1, further including receiving the reference output response from a memory communicative with the controller.

6. A method as recited in claim 1, wherein applying a diagnostic signal to the sensor includes re-connecting the sensor to a sensor power supply.

7. A method as recited in claim 1, wherein receiving the dynamic output response includes receiving a positive transient voltage.

8. A method as recited in claim 1, further including executing an independent built-in-test of the sensor.

9. A method as recited in claim 1, wherein the sensor includes an accelerometer coupled to a mechanical component of a rotary wing aircraft.

10. A method as recited in claim 1, wherein the sensor includes an integrated electronic piezoelectric accelerometer.

11. A method as recited in claim 1, wherein the sensor is a first sensor, applying a diagnostic signal includes changing voltage applied to both the first sensor and a second sensor, receiving dynamic output includes receiving a dynamic output response from each of the first and second sensors, and further including cross-correlating dynamic output responses of both the first and second sensors.

12. A method of assessing health of a sensor, comprising:
disconnecting a sensor from a power supply using a controller;
receiving a dynamic output response from the sensor including a negative transient voltage;
re-connecting the sensor to the power supply using the controller;
receiving a dynamic output response from the sensor including a positive transient voltage;
comparing the dynamic output responses following the disconnect and re-connect events with reference output responses associated with the disconnect and re-connect events; and
indicating that the sensor is unreliable if either or both of the dynamic output responses differ from the reference output responses a predetermined value for a dynamic output response parameter.

13. A method as recited in claim 12, further including conducting a built-in-test event independent of the disconnection and connection dynamic and reference output response comparison.

14. A method as recited in claim 12, wherein both the sensor includes an integrated electronic piezoelectric accelerometer.

15. A method as recited in claim 12, wherein disconnecting includes disconnecting first and second sensors from a power supply, wherein re-connecting includes re-connecting both the first and second sensors to the power supply, and further including cross-correlating dynamic output responses of both the first and second sensors subsequent to the disconnect and re-connect events.

16. A system for assessing condition of a sensor, comprising:
a sensor configured to couple to an aircraft mechanical component;
a power supply connectable to the sensor;
a processor operably associated with the power supply; and
a memory communicative with the processor and having instruction recorded thereon that, when read by the processor, cause the processor to:
change a voltage applied to the sensor by the power supply;
receive a dynamic output response from the sensor, wherein the dynamic output response includes a transient and a return to a baseline sensor output voltage;
compare the dynamic output response to a reference output response; and
indicate that the sensor is unreliable if the dynamic output response differs from the reference output response by a predetermined value for a dynamic output response output parameter.

17. A system as recited in claim 16, wherein the instructions further cause the processor to conduct a built-in-test independent of the dynamic output response and reference output response comparison.

18. A system as recited in claim 16, wherein the instructions cause the processor to sequentially (a) change the voltage applied to the sensor by disconnecting the sensor from the power supply, (b) receive a first dynamic output response associated with the disconnect event, (c) re-connect the sensor to the power supply, and (d) receive a second dynamic output response associated with re-connect event.
